(19) United States
(12) Patent Application Publication
(10) Pub. No.: US 2014/0102521 A1
(43) Pub. Date: Apr. 17, 2014

(54) THIN FILM SILICON SOLAR CELL

(71) Applicant: Electronics and Telecommunications Research Institute, (US)

(72) Inventors: JungWook LIM, Daejeon (KR); Sun Jin YUN, Daejeon (KR); Seong Hyun LEE, Busan (KR); Da Jung LEE, Gyeongsangbuk-do (KR)

(73) Assignee: Electronics and Telecommunications Research Institute, Daejeon (KR)

(21) Appl. No.: 13/842,059

(22) Filed: Mar. 15, 2013

(30) Foreign Application Priority Data
Oct. 11, 2012 (KR) 10-2012-0112921

(51) Int. Cl. H01L 31/0392; H01L 31/076; H01L 31/0376; H01L 31/075; H01L 31/0368

(52) U.S. Cl. CPC H01L 31/0392; H01L 31/075; H01L 31/03685; H01L 31/03762; H01L 31/076; H01L 31/03921
USPC 136/255

(57) ABSTRACT

Provided is a thin film silicon solar cell including a first optical absorption layer, a first transparent electrode disposed in a surface of the first optical absorption layer, a first transparent substrate covering the first transparent electrode, a second transparent electrode disposed another surface of the first optical absorption layer, and a second transparent substrate covering the second transparent electrode, wherein the first optical absorption layer has a thickness of about 500 Å to about 2000 Å.

### CROSS-REFERENCE TO RELATED APPLICATIONS

This U.S. non-provisional patent application claims priority under 35 U.S.C. §119 of Korean Patent Application No. 10-2012-0112921, filed on Oct. 11, 2012, the entire contents of which are hereby incorporated by reference.

### BACKGROUND OF THE INVENTION

The present invention disclosed herein relates to a thin film silicon solar cell, and more particularly, to a thin film silicon solar cell in which light can be incident to two sides thereof.

A solar cell is a photovoltaic energy conversion system for converting light energy emitted from the sun to electrical energy. A crystalline silicon solar cell occupies most of the solar cell market. The crystalline solar cell is hard to be realized with various shapes and materials. However a thin film silicon solar cell may be realized with various shapes and materials. In addition, a material of the thin film silicon solar cell has advantages of being non-toxic, abundant and stable.

### SUMMARY OF THE INVENTION

The present invention provides a thin film silicon solar cell in which light can be incident to two sides thereof.

Embodiments of the present invention provide thin film silicon solar cells including a first optical absorption layer; a first transparent electrode disposed on a surface of the first optical absorption layer; a first transparent substrate covering the first transparent electrode; a second transparent electrode disposed on another surface of the first optical absorption layer; and a second transparent substrate covering the second transparent electrode, wherein the first optical absorption layer has a thickness of about 500 Å to about 2000 Å.

In some embodiments, the first optical absorption layer may be an amorphous silicon layer or microcrystalline silicon layer.

In other embodiments, the first optical absorption layer may comprise silicon-germanium, silicon oxide, silicon nitride or silicon carbide.

In still other embodiments, the first and second electrodes may be formed of any one of ITO, ZnO:Al, ZnO:Ga, SnO2:F and ZnO:B.

In even other embodiments, the first optical absorption layer may comprise a P-layer, an I-layer and an N-layer laminated sequentially.

In yet other embodiments, the I-layer may have greater thickness than the N-layer and P-layer.

In further embodiments, a second optical absorption layer between the first optical absorption layer and the second transparent electrode may be further comprised.

In still further embodiments, the first optical absorption layer may comprise microcrystalline silicon or microcrystalline silicon-germanium.

In even further embodiments, the second optical absorption layer may comprise amorphous silicon or amorphous silicon-germanium.

In yet further embodiments, the first and second optical absorption layers may have different energy gaps.

In much further embodiments, the first optical absorption layer may have an energy gap of about 1.1 eV to about 1.7 eV.

In still much further embodiments, the second optical absorption layer may have an energy gap of about 1.5 eV to about 1.9 eV.

In even much further embodiments, the second optical absorption may comprise a P-layer, an I-Layer and an N-layer laminated sequentially.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view of a thin film silicon solar cell according to an embodiment of the present invention;

FIG. 2 is a cross-sectional view of a thin film silicon solar cell according to another embodiment of the present invention; and

FIG. 3 illustrates a graph for comparing current-to-voltage characteristics when light is incident to one side and two sides of the thin film solar cell of the embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout.

The terminology used herein is for the purpose of describing particular embodiments only and is not intended to be limiting of example embodiments. It will be understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional view and/or plan view illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes may be not intended to illustrate the actual shape of a region of a device and are not intended to limit the scope of example embodiments.

In the drawings, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Hereinafter, it will be described about an exemplary embodiment of the present invention in conjunction with the accompanying drawings.

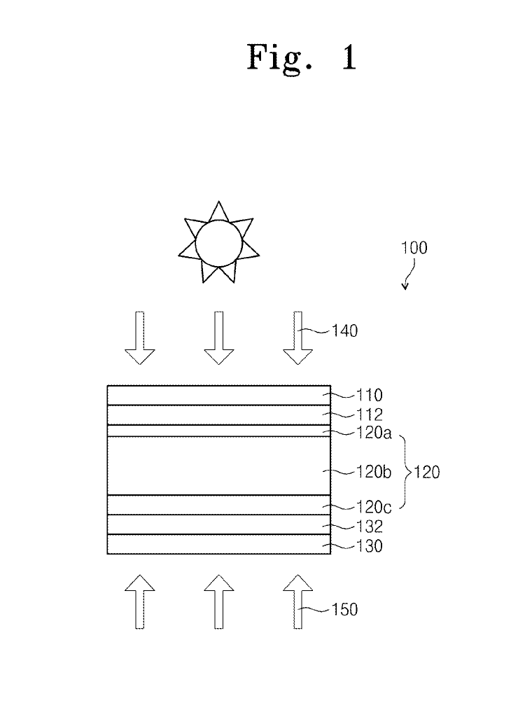

FIG. 1 is a cross-sectional view of a thin film silicon solar cell according to an embodiment of the present invention.

Referring to FIG. 1, a thin film solar cell 100 includes an optical absorption layer 120. A first transparent electrode 112 and a first substrate 110 may be sequentially disposed on one surface of the optical absorption layer 120. A second transparent electrode 132 and a second substrate 130 are sequentially disposed on another surface of the optical absorption layer 120.

The first substrate 110 and second substrate 130 may be a transparent glass substrate. First light 140 may be incident to the first substrate 110 and second light 150 may be incident to the second substrate 130. The first light 140 may be sun light. The second light 150 is light other than sun light or reflected sun light.

The first and second transparent electrodes 112 and 132 may be formed of a transparent conductive material. The first and second transparent electrodes 112 and 132 may be formed of one of for example ITO, ZnO:Al, ZnO:Ga, SnO₂:F and ZnO:B

The optical absorption layer 120 may be one layer and/or a multi-layer. The optical absorption layer 120 may be a silicon layer. In detail, the optical absorption layer 120 may be an amorphous silicon layer a-Si:H or a microcrystalline silicon layer μc-Si:H. The optical absorption 120 may include silicon-germanium, silicon oxide, silicon nitride or silicon carbide.

The optical absorption layer 120 may be disposed between the first and second transparent electrodes 112 and 132, and include a laminated structure of a P-layer 120a, an I-layer 120b and an N-layer 120c in order. The P-layer 120a included in the optical absorption layer 120 may be closely disposed to the first substrate 110. Alternatively the N-layer 120c included in the optical absorption layer 120 may be closely disposed to the first substrate 110. The P-layer 120a may be a silicon layer with a p-type impurity doped, the I-layer 120b may be an intrinsic semiconductor layer without an impurity doped, and the N-layer 120c may be a layer with an n-type impurity doped. The P-layer 120a may be a layer with a group III element such as boron B, gallium Ga, Indium In doped. The N-layer 120c may be a layer with a group V element such as phosphorous P, arsenic As, antimony Sb doped. The optical absorption layer 120 may have a thickness of about 500 Å to about 2000 Å. When the optical absorption layer 120 has a thickness of about 2000 Å or more, light is hard to transmit through the solar cell so that realization of the transparent solar cell is hard. Additionally when the optical absorption layer 120 has less than a thickness of about 500 Å, the function of the optical absorption layer 120 is hard to be realized. The N-layer 120c may have greater thickness than the P-layer 120a. The I-layer 120b may have greater thickness than the P-layer 120a and N-layer 120c. In detail, when the optical absorption layer 120 has a thickness of about 2000 Å, the P-layer 120a may have a thickness of about 100 Å to about 180 Å, the I-layer 120b may have a thickness of about 1500 Å and the N-layer 120c may have a thickness of about 250 Å to about 350 Å.

The first light 140 incident to the first substrate 110 transmits through the first transparent electrode 112 to be absorbed into the optical absorption layer 120. The second light 150 incident to the second substrate 130 transmits through the second transparent electrode 132 to be absorbed into the optical absorption layer 120. The I-layer 120b in the optical absorption layer 120 is depleted by the N-layer 120a and P-layer 120c and an electric field is generated therein. An electron-hole pair is generated in the I-layer 120b by the first and second lights 140 and 150. The electron is collected in the N-layer 120a, the hole is collected in the P-layer 120c by the electric field, and then a current flows.

The hole has lower mobility than the electron, and the hole collecting speed in the P-layer is different from the electron collecting speed in the N-layer. Namely, the light efficiency of the solar cell changes according to a light irradiation direction. When the light is incident to two sides of the solar cell, the electron and hole can be effectively colleted to have constant light efficiency. Thus, the light efficiency of the solar cell is improved since the light is absorbed at the two sides.

Typically when the light efficiency is high, a transparent solar cell having high efficiency is hard to be realized due to low transmittivity. In order to solve this limitation, the optical absorption layer 120 is formed thin. Then the thin film silicon solar cell 100 having high transmittivity and light efficiency can be formed by outputting the first light 140 which is not absorbed into the optical absorption layer 120 to outside through the second substrate 130 and outputting the second light 150 to outside through the first substrate 110 after the light incident to the two sides is absorbed into the optical absorption layer 120.

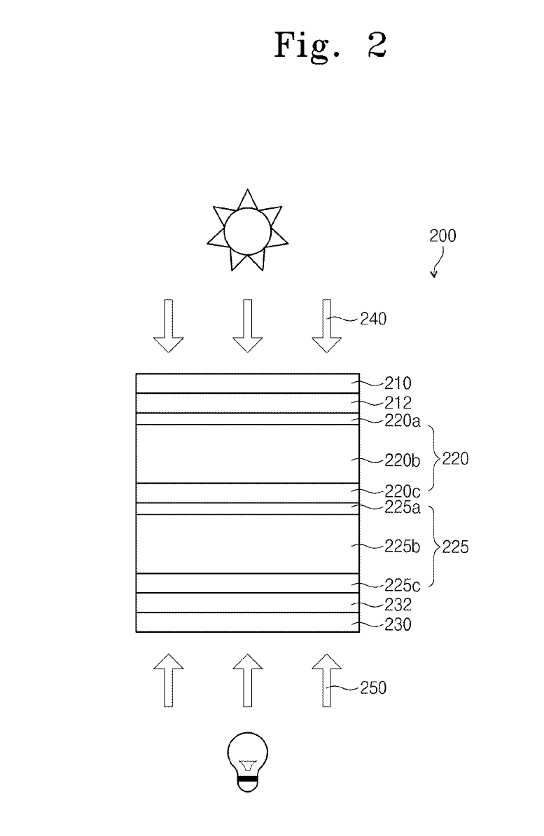

FIG. 2 is a cross-sectional view of a thin film silicon solar cell according to another embodiment of the present invention.

Referring to FIG. 2, a thin film silicon solar cell 200 includes a first optical absorption layer 220. A first transparent electrode 212 and a first substrate 210 may be sequentially disposed on one surface of the optical absorption layer 220. A second optical absorption layer 250, a second transparent electrode 232 and a second substrate 230 may be sequentially disposed on another surface of the optical absorption layer 220.

The first substrate 210 and second substrate 230 may be a transparent glass substrate. First light 240 may be incident to the first substrate 210 and second light 250 may be incident to the second substrate 230. The first light 240 may be sun light. The second light 250 is light other than sun light. The second light 250 may be light from, for example, a fluorescent tube or a light emitting diode (LED).

The first and second transparent electrodes 212 and 232 may be formed of a transparent conductive material. The first and second transparent electrodes 212 and 232 may be formed of one of for example ITO, ZnO:Al, ZnO:Ga, SnO₂:F and ZnO:B.

The first optical absorption layer 220 may be a microcrystalline silicon layer μc-Si:H or an amorphous silicon. In detail, the microcrystalline silicon layer μc-Si:H may include microcrystalline silicon-germanium. The first optical absorption layer 220 may include a laminated structure of a P-layer 220a, an I-layer 220b and an N-layer 220c sequentially. The P-layer 220a may be a silicon layer with a p-type impurity doped, the I-layer 220b may be an intrinsic semiconductor layer without an impurity doped, and the N-layer 220c may be a layer with an n-type impurity doped. Positions of the P-layer 220a and N-layer 220c may be changed. Accordingly the first optical absorption layer 220 may have a pin structure or a nip structure. The first optical absorption layer 220 may have a thickness of about 500 Å to about 2000 Å. The N-layer 220c may have greater thickness than the P-layer 220a. The I-layer 220b may have greater thickness than the P-layer 220a and N-layer 220c. In detail, when the first optical absorption layer 220 has a thickness of about 2000 Å, the P-layer 220a may have a thickness of about 150 Å, the I-layer 220b may have about 1500 Å thickness and the N-layer 220c may have a thickness of about 350 Å. The microcrystalline silicon layer c-Si:H may have from few tens of nm to few hundreds of nm crystal size and may have an energy gap of about 1.1 eV to about 1.7 eV.

The second optical absorption layer 225 may be an amorphous silicon layer a-Si:H. The first optical absorption layer 220 may include, for example, an amorphous silicon or amorphous silicon-germanium. The second optical absorption layer 225 may include a P-layer 225a, an I-layer 225b and an N-layer 225c. The second optical absorption layer 225 may have the same structure as the first optical absorption layer 220. For example, when the first optical absorption layer 220 has a pin structure, the second optical absorption layer 225 may have the pin structure. When the first optical absorption layer 220 has a nip structure, the second optical absorption layer 225 may have the nip structure. In addition, the second optical absorption layer 225 may be formed to have the same thickness as the first optical absorption layer 220. The amorphous silicon layer a-Si:H has an energy gap of about 1.5 eV to about 1.9 eV.

The first light 240 incident to the first substrate 210 transmits the first transparent electrode 212 to be absorbed into the first optical absorption layer 220. The first light 240 includes visible light, infrared light and ultraviolet light. The first optical absorption layer 220 may absorb the visible light and infrared light of the first light 240 to the maximum.

The second light 250 incident to the second substrate 230 transmits through the second transparent electrode 232 to be absorbed into the second optical absorption layer 225. The second light 250 includes ultraviolet light as the fluorescence or LED light. The second optical absorption layer 225 may absorb the ultraviolet light of the second light 250 to the maximum. The ultraviolet light of the first light 240 which is not absorbed into the first optical absorption layer 220 may be absorbed into the second optical absorption layer 225 and a portion of light of the second light 250 which is not absorbed into the second optical absorption layer 250 may be absorbed into the first optical absorption layer 220.

When wavelengths of the light incident to two sides of a solar cell are different, a light absorption amount may be maximized by disposing optical absorption layers of which energy gaps are different from each other. Since the optical absorption layers are disposed in plural and light which is not absorbed into a first optical absorption layer may be absorbed into a second optical absorption layer, light efficiency of the thin film silicon solar cell 200 may be improved.

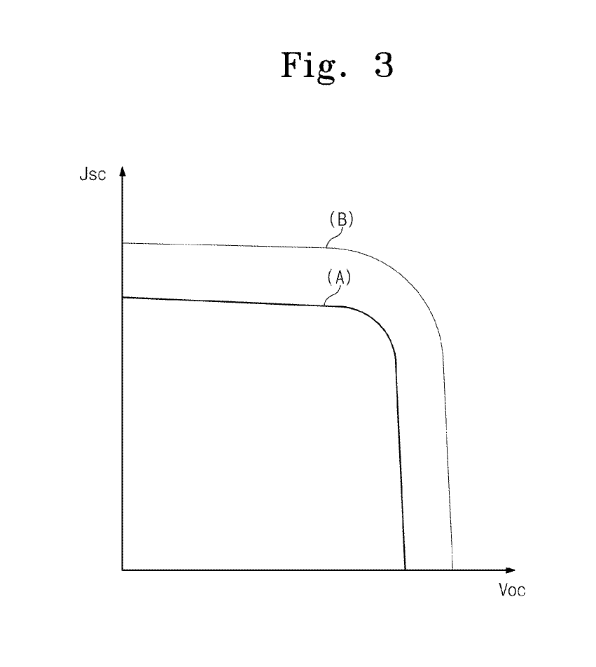

FIG. 3 illustrates a graph for comparing current-to-voltage characteristics when light is incident to one side and two sides of the thin film solar cell of the embodiment of the present invention.

Referring to FIG. 3, (A) indicates a solar cell in which light is incident to one side and (B) indicates a solar cell in which light is incident to two sides.

It can be confirmed that the solar cell (B) in which light is incident to two sides generates greater light current than the solar cell (A) in which light is incident to one side. Namely, the greater an amount of incident light is, the greater an amount of light current generated in the solar cell is.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A thin film silicon solar cell comprising:
a first optical absorption layer;
a first transparent electrode disposed on a surface of the first optical absorption layer;
a first transparent substrate covering the first transparent electrode;
a second transparent electrode disposed on another surface of the first optical absorption layer; and
a second transparent substrate covering the second transparent electrode, wherein the first optical absorption layer has a thickness of about 500 Å to about 2000 Å.

2. The thin film silicon solar cell of claim 1, wherein the first optical absorption layer is an amorphous silicon layer or microcrystalline silicon layer.

3. The thin film silicon solar cell of claim 1, wherein the first optical absorption layer comprises silicon-germanium, silicon oxide, silicon nitride or silicon carbide.

4. The thin film silicon solar cell of claim 1, wherein the first and second electrodes are formed of any one of ITO, ZnO:Al, ZnO:Ga, SnO₂:F and ZnO:B.

5. The thin film silicon solar cell of claim 1, wherein the first optical absorption layer comprises a P-layer, an I-layer and an N-layer laminated sequentially.

6. The thin film silicon solar cell of claim 5, wherein the I-layer has greater thickness than the N-layer and P-layer.

7. The thin film silicon solar cell of claim 1, further comprising a second optical absorption layer between the first optical absorption layer and the second transparent electrode.

8. The thin film silicon solar cell of claim 7, wherein the first optical absorption layer comprises microcrystalline silicon or microcrystalline silicon-germanium.

9. The thin film silicon solar cell of claim 7, wherein the second optical absorption layer comprises amorphous silicon or amorphous silicon-germanium.

10. The thin film silicon solar cell of claim 7, wherein the first and second optical absorption layers have different energy gaps.

11. The thin film silicon solar cell of claim 10, wherein the first optical absorption layer has an energy gap of about 1.1 eV to about 1.7 eV.

12. The thin film silicon solar cell of claim 10, wherein the second optical absorption layer has an energy gap of about 1.5 eV to about 1.9 eV.

13. The thin film silicon solar cell of claim 7, wherein the second optical absorption comprises a P-layer, an I-Layer and an N-layer laminated sequentially.
